(19) United States
(12) Patent Application Publication
(10) Pub. No.: US 2026/0293710 A1
(43) Pub. Date: Sep. 24, 2026

(54) POWER MODULE

(71) Applicant: Mitsubishi Electric Corporation, Tokyo (JP)

(72) Inventors: Shota SAITO, Fukuoka (JP); Yuki MATSUTAKA, Tokyo (JP); Hodaka ROKUBUICHI, Tokyo (JP); Satoshi MIYAHARA, Chiyoda-ku, Tokyo (JP); Toshiya TADAKUMA, Tokyo (JP)

(73) Assignee: Mitsubishi Electric Corporation, Tokyo (JP)

(21) Appl. No.: 19/455,202

(22) Filed: Jan. 21, 2026

(30) Foreign Application Priority Data
Mar. 19, 2025 (JP) JP2025-045329

(51) Int. Cl. H10W 70/40; H10W 72/50

(52) U.S. Cl. CPC H10W 70/481; H10W 70/442; H10W 72/541

(57) ABSTRACT

A power module according to the present disclosure includes a switching device group that includes: a first switching device; a second switching device; a first frame connected to a high voltage potential part of the first switching device and having a first terminal; a second frame connected to a reference potential part of the second switching device and having a second terminal; a third frame connected to a reference potential part of the first switching device and a high voltage potential part of the second switching device and having a third terminal; a fourth terminal connected to a control potential part of the first switching device; a fifth terminal connected to the reference potential part of the first switching device; a sixth terminal connected to a control potential part of the second switching device; and a seventh terminal connected to the reference potential part of the second switching device.

### BACKGROUND

### Technical Field

The present disclosure relates to a power module including a switching device.

### Description of the Background Art

When a power module including a metal oxide semiconductor field effect transistor (MOSFET) as a switching device is driven at a high frequency, it is necessary to reduce switching loss (see, for example, Japanese Patent Application Laid-Open No. 2022-92545).

In order to reduce the switching loss, it is necessary to increase the switching speed. However, when the switching speed is increased, a voltage drop (V_{SS}=L_{S_SS}×di/dt) due to a main current I_{D} flowing between a drain and a source and the parasitic inductance L_{S_SS} on the power module and a substrate increases, so that the voltage drop of a gate voltage V_{GS} increases. This leads to the problem of an increase in switching loss.

### SUMMARY

An object of the present disclosure is to provide a power module capable of reducing switching loss.

A power module according to the present disclosure includes a package and at least one switching device group disposed inside the package, wherein the switching device group includes: a first switching device that is disposed inside the package and serves as an upper arm; a second switching device that is disposed inside the package and serves as a lower arm; a first frame that is disposed inside the package, is connected to a high voltage potential part of the first switching device, and has a first terminal that is a portion protruding outside the package; a second frame that is disposed inside the package, is connected to a reference potential part of the second switching device, and has a second terminal that is a portion protruding outside the package; a third frame that is disposed inside the package, is connected to each of a reference potential part of the first switching device and a high voltage potential part of the second switching device, and has a third terminal that is a portion protruding outside the package; a fourth terminal that is connected to a control potential part of the first switching device without passing through the first frame, the second frame, and the third frame and protrudes outside the package; a fifth terminal that is connected to the reference potential part of the first switching device without passing through the first frame, the second frame, and the third frame and protrudes outside the package; a sixth terminal that is connected to a control potential part of the second switching device without passing through the first frame, the second frame, and the third frame and protrudes outside the package; and a seventh terminal that is connected to the reference potential part of the second switching device without passing through the first frame, the second frame, and the third frame and protrudes outside the package.

According to the present disclosure, switching loss can be reduced.

These and other objects, features, aspects and advantages of the present disclosure will become more apparent from the following detailed description of the present disclosure when taken in conjunction with the accompanying drawings.

### BRIEF DESCRIPTION OF THE DRAWINGS

FIG. 1 is a plan view illustrating a configuration of a power module according to a first preferred embodiment;

FIG. 2 is a circuit diagram of the power module according to the first preferred embodiment;

FIG. 3 is a plan view illustrating a configuration of a power module according to a second preferred embodiment;

FIG. 4 is a plan view illustrating a configuration of a power module according to a third preferred embodiment;

FIG. 5 is a plan view illustrating a configuration of a power module according to a fourth preferred embodiment;

FIG. 6 is a side view illustrating a configuration of a power module according to a fifth preferred embodiment;

FIG. 7 is a side view illustrating a configuration of a power module according to a first modification of the fifth preferred embodiment; and

FIG. 8 is a side view illustrating a configuration of a power module according to a second modification of the fifth preferred embodiment.

### DESCRIPTION OF THE PREFERRED EMBODIMENTS

### First Preferred Embodiment

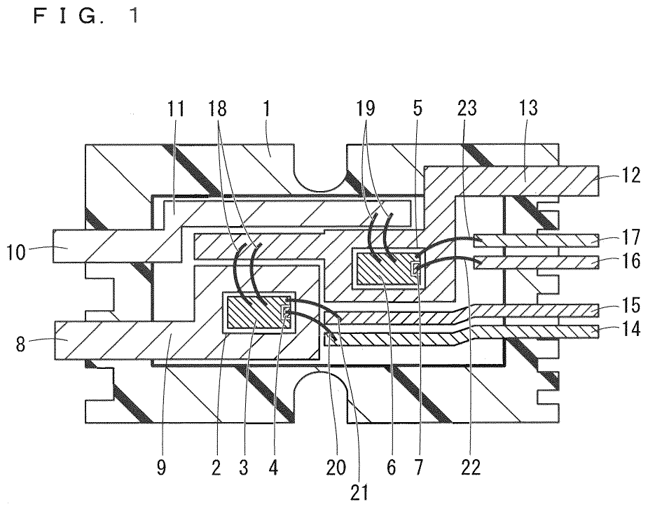

FIG. 1 is a plan view illustrating a configuration of a power module according to a first preferred embodiment. The power module includes a package 1 and a semiconductor chip group (switching device group) disposed inside the package 1. The package 1 is made of resin. The semiconductor chip group includes a first semiconductor chip 2, a second semiconductor chip 5, a first frame 9, a second frame 11, a third frame 13, a fourth terminal 14, a fifth terminal 15, a sixth terminal 16, and a seventh terminal 17.

The first semiconductor chip 2 (first switching device) is disposed inside the package 1 and constitutes an upper arm. The first semiconductor chip 2 is a MOSFET including a first source electrode 3 (reference potential part), a first gate electrode 4 (control potential part), and a first drain electrode (high voltage potential part) (not illustrated).

The second semiconductor chip 5 (second switching device) is disposed inside the package 1 and constitutes a lower arm. The second semiconductor chip 5 is a MOSFET including a second source electrode 6 (reference potential part), a second gate electrode 7 (control potential part), and a second drain electrode (high voltage potential part) (not illustrated).

The present disclosure will describe a case where the first semiconductor chip 2 and the second semiconductor chip 5 are MOSFETs, but the first semiconductor chip 2 and the second semiconductor chip 5 may be a switching device such as an insulated gate bipolar transistor (IGBT) or a reverse conducting IGBT (RC-IGBT). For example, when the first semiconductor chip 2 and the second semiconductor chip 5 are IGBTs, the first source electrode 3 and the second source electrode 6 may be replaced with a first emitter electrode and a second emitter electrode, respectively, and the first drain electrode and the second drain electrode may be replaced with a first collector electrode and a second collector electrode, respectively.

The first frame 9 is disposed inside the package 1 and connected to the first drain electrode of the first semiconductor chip 2. In addition, the first frame 9 has a first terminal 8 which is a portion protruding outward from the package 1. The first terminal 8 corresponds to a drain terminal (high voltage potential terminal) of the upper arm.

The second frame 11 is disposed inside the package 1 and is connected to the second source electrode 6 of the second semiconductor chip 5 via a wire 19. In addition, the second frame 11 has a second terminal 10 which is a portion protruding outward from the package 1. The second terminal 10 corresponds to a source terminal (reference potential terminal) of the lower arm.

The third frame 13 is disposed inside the package 1, is connected to the first source electrode 3 of the first semiconductor chip 2 via a wire 18, and is connected to the second drain electrode of the second semiconductor chip 5. In addition, the third frame 13 has a third terminal 12 which is a portion protruding outward from the package 1. The third terminal 12 corresponds to the source terminal (reference potential terminal) of the upper arm and corresponds to the drain terminal (high voltage potential terminal) of the lower arm.

The fourth terminal 14 is connected to the first gate electrode 4 of the first semiconductor chip 2 via a wire 20 without passing through the first frame 9, the second frame 11, and the third frame 13. The fourth terminal 14 protrudes outward from the package 1.

The fifth terminal 15 is connected to the first source electrode 3 of the first semiconductor chip 2 via a wire 21 without passing through the first frame 9, the second frame 11, and the third frame 13. The fifth terminal 15 protrudes outward from the package 1. The fifth terminal 15 corresponds to a reference potential control terminal.

The sixth terminal 16 is connected to the second gate electrode 7 of the second semiconductor chip 5 via a wire 22 without passing through the first frame 9, the second frame 11, and the third frame 13. The sixth terminal 16 protrudes outward from the package 1.

The seventh terminal 17 is connected to the second source electrode 6 of the second semiconductor chip 5 via a wire 23 without passing through the first frame 9, the second frame 11, and the third frame 13. The seventh terminal 17 protrudes outward from the package 1. The seventh terminal 17 corresponds to a reference potential control terminal.

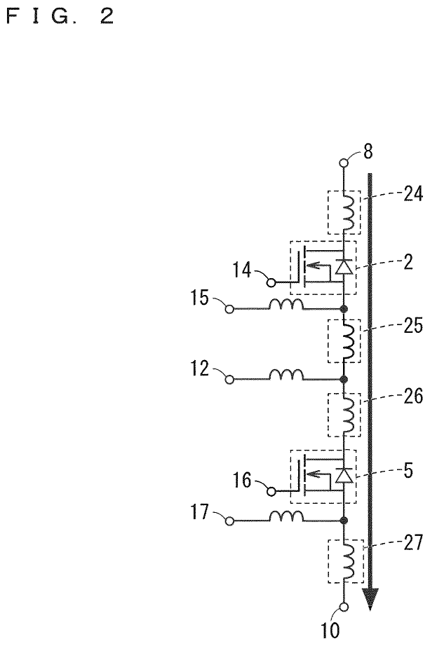

FIG. 2 is a circuit diagram of the power module according to the first preferred embodiment. In FIG. 2, a downward arrow illustrated on the right side of the circuit indicates a direction in which a main current I_{D} flows.

The parasitic inductance 24 indicates a parasitic inductance caused by the first frame 9. The parasitic inductance 25 is inductance caused by the source terminal (third terminal 12) of the upper arm of the third frame 13. The parasitic inductance 26 is inductance caused by the drain terminal (third terminal 12) of the lower arm of the third frame 13. The parasitic inductance 27 is inductance caused by the second frame 11.

As illustrated in FIG. 2, in the package 1, the fifth terminal 15 and the seventh terminal 17 are connected to a path different from a path through which the main current I_{D} flows. For example, when a gate voltage V_{GS} for driving the second semiconductor chip 5 is applied between the sixth terminal 16 and the seventh terminal 17, the main current I_{D} is not applied to the seventh terminal 17, so that the voltage drop of the gate voltage V_{GS} is reduced. As a result, the gate voltage V_{GS} becomes close to an input voltage, whereby a turn-on switching loss and a turn-off switching loss are reduced.

The package inductance, which is the inductance between the first terminal 8 and the second terminal 10, is 20 nH or less. In FIG. 2, the package inductance is the sum of parasitic inductances 24, 25, 26, and 27 and is the combined inductance of inductances caused by wires and frames, for example.

In a power factor correction (PFC), which is a conventional way of operating a power module, a frequency of 20 to 50 kHz is used. The package inductance at that time is 30 to 50 nH. On the other hand, in an on-board charger (OBC) used for rapid charging of a battery of an electric vehicle, or the like, a frequency of 100 kHz is used. Since the switching loss increases as the switching frequency increases, the package inductance needs to be smaller in the OBC than in the PFC. The power module according to the first preferred embodiment has a package inductance of 20 nH or less, and thus can be applied to the OBC.

According to the first preferred embodiment, the fifth terminal 15 and the seventh terminal 17 are connected to a path different from the path through which the main current I_{D} flows inside the package 1, whereby the voltage drop of the gate voltage V_{GS} is reduced, and the switching loss can be reduced.

### Second Preferred Embodiment

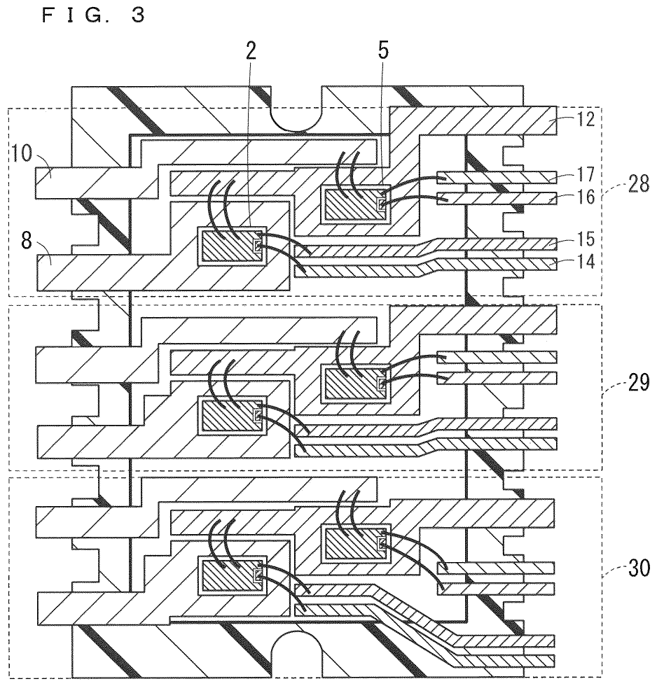

FIG. 3 is a plan view illustrating a configuration of a power module according to a second preferred embodiment. The power module according to the second preferred embodiment includes a plurality of semiconductor chip groups 28, 29, and 30. The configuration of each of the semiconductor chip groups 28, 29, and 30 is similar to that of the semiconductor chip group (see FIG. 1) according to the first preferred embodiment, so that the detailed description thereof is omitted here.

As illustrated in FIG. 3, the semiconductor chip groups 28, 29, and 30 are aligned in one direction inside a package 1.

In the example of FIG. 3, three semiconductor chip groups 28, 29, and 30 are arranged inside the package 1 of the power module to form a three-phase structure.

In the power module, for example, two semiconductor chip groups 28 and 29 may be arranged inside the package 1 to form a full-bridge circuit.

According to the second preferred embodiment, the switching loss can be reduced as in the first preferred embodiment, and the power module can be stably operated. In addition, since a plurality of semiconductor chip groups is arranged inside one package, it is possible to reduce the mounting area in a circuit configuration of an OBC, or the like.

### Third Preferred Embodiment

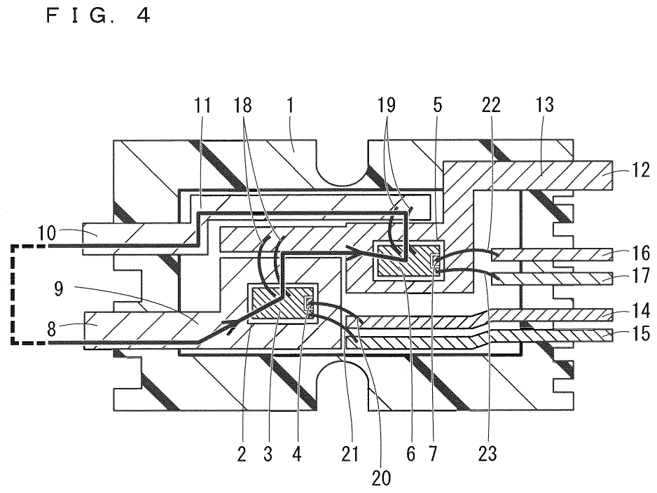

FIG. 4 is a plan view illustrating a configuration of a power module according to a third preferred embodiment. In FIG. 4, an arrow indicates a path of a main current flowing through the power module.

In the power module according to the third preferred embodiment, a connection point between a wire 21 and a first source electrode 3 in a first semiconductor chip 2 is located in a region where the current density of the main current is low. In a second semiconductor chip 5, a connection point between a wire 23 and a second source electrode 6 is located in a region where the current density of the main current is low. The other configurations are similar to those of the power module (FIG. 1) according to the first preferred embodiment, and thus the detailed description thereof is omitted here. Each of the first semiconductor chip 2 and the second semiconductor chip 5 will be specifically described below.

First, the first semiconductor chip 2 will be described.

As illustrated in FIG. 4, a first connection point at which one end of a wire 18 is connected to the first source electrode 3 of the first semiconductor chip 2 is located closer to the end with respect to the center of the first semiconductor chip 2. A second connection point at which one end of the wire 21 is connected to the first source electrode 3 of the first semiconductor chip 2 is located on the side opposite to the first connection point with respect to the center of the first semiconductor chip 2. As described above, the second connection point is located in a region (region where the current density of the main current is low) away from the first connection point where the current density of the main current is high.

As another example, the first connection point may be located at the center of the first semiconductor chip 2. In this case, the second connection point may be located at the end of the first semiconductor chip 2. As a result, the second connection point can be disposed in a region away from the first connection point where the current density of the main current is high.

As illustrated in FIG. 4, the second connection point may be adjacent to a third connection point at which one end of a wire 20 is connected to a first gate electrode 4 of the first semiconductor chip 2. The second connection point may have a longer distance from the first connection point than the third connection point.

Next, the second semiconductor chip 5 will be described.

As illustrated in FIG. 4, a fourth connection point at which one end of a wire 19 is connected to the second source electrode 6 of the second semiconductor chip 5 is located closer to the end with respect to the center of the second semiconductor chip 5. A fifth connection point at which one end of the wire 23 is connected to the second source electrode 6 of the second semiconductor chip 5 is located on the side opposite to the fourth connection point with respect to the center of the second semiconductor chip 5. As described above, the fifth connection point is located in a region (region where the current density of the main current is low) away from the fourth connection point where the current density of the main current is high.

As another example, the fourth connection point may be located at the center of the second semiconductor chip 5. In this case, the fifth connection point may be located at the end of the second semiconductor chip 5. As a result, the fifth connection point can be disposed in a region away from the fourth connection point where the current density of the main current is high.

As illustrated in FIG. 4, the fifth connection point may be adjacent to a sixth connection point at which one end of a wire 22 is connected to a second gate electrode 7 of the second semiconductor chip 5. The fifth connection point may have a longer distance from the fourth connection point than the sixth connection point.

According to the third preferred embodiment, the second connection point of the wire 21 in the first semiconductor chip 2 and the fifth connection point of the wire 23 in the second semiconductor chip 5 are disposed in regions away from the position where the current density of the main current is high, whereby the voltage drop of the gate voltage due to the switching operation of the first semiconductor chip 2 and the second semiconductor chip 5 is reduced, and the switching loss can be reduced.

### Fourth Preferred Embodiment

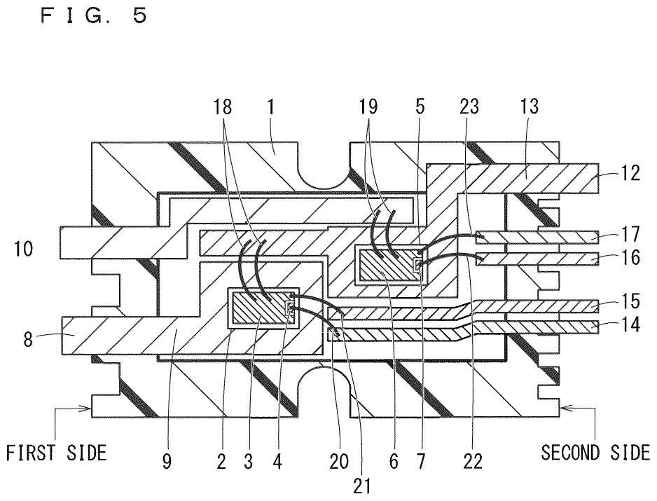

FIG. 5 is a plan view illustrating a configuration of a power module according to a fourth preferred embodiment. In the power module according to the fourth preferred embodiment, a first terminal 8 and a second terminal 10 are disposed on a first side of a package 1. A third terminal 12, a fourth terminal 14, a fifth terminal 15, a sixth terminal 16, and a seventh terminal 17 are disposed on a second side of the package 1. The first side and the second side face each other. The other configurations are similar to those of the power module (FIG. 1) according to the first preferred embodiment, and thus the detailed description thereof is omitted here.

The first terminal 8 and the second terminal 10 which are on the input terminal side of the power module are separated from the third terminal 12, the fourth terminal 14, the fifth terminal 15, the sixth terminal 16, and the seventh terminal 17 which are on the output terminal side, whereby an electrolytic capacitor and a snubber capacitor can be mounted on the input terminal side and a resonance capacitor can be mounted on the output terminal side. That is, the mounting components can be disposed separately on the input terminal side and the output terminal side.

When the power module is used for OBC, it is necessary to reduce the parasitic inductance of a main circuit as much as possible. In the fourth preferred embodiment, the side on which the first terminal 8 and the second terminal 10 are disposed and the side on which the third terminal 12, the fourth terminal 14, the fifth terminal 15, the sixth terminal 16, and the seventh terminal 17 are disposed face each other, whereby the parasitic inductance (package inductance) of the main circuit can be reduced.

The side on which the first terminal 8 and the second terminal 10 are disposed and the side on which the third terminal 12, the fourth terminal 14, the fifth terminal 15, the sixth terminal 16, and the seventh terminal 17 are disposed may not face each other, but the parasitic inductance of the main circuit increases when both sides do not face each other, which is not preferable.

### Fifth Preferred Embodiment

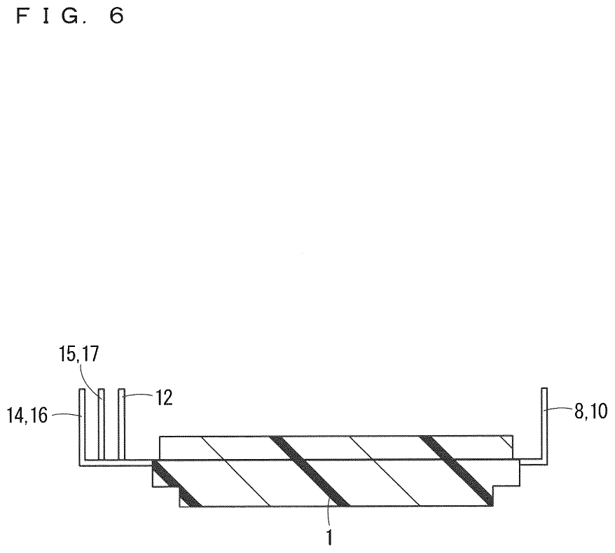

FIG. 6 is a side view illustrating a configuration of a power module according to a fifth preferred embodiment. In the power module according to the fifth preferred embodiment, the leading ends of the first terminal 8, the second terminal 10, the third terminal 12, the fourth terminal 14, the fifth terminal 15, the sixth terminal 16, and the seventh terminal 17 are oriented in a direction perpendicular to the first frame 9, the second frame 11, and the third frame 13. The other configurations are similar to those of the power module (FIG. 1) according to the first preferred embodiment, and thus the detailed description thereof is omitted here.

In FIG. 6, the fifth terminal 15 and the seventh terminal 17 protrude outward from the third terminal 12, and the fifth terminal 15 and the seventh terminal 17 appear to overlap each other when the power module is viewed from the side surface. In addition, the fourth terminal 14 and the sixth terminal 16 protrude outward from the fifth terminal 15 and the seventh terminal 17, and the fourth terminal 14 and the sixth terminal 16 appear to overlap each other when the power module is viewed from the side surface.

When the power module is viewed from above, the third terminal 12, a set of the fifth terminal 15 and the seventh terminal 17, and a set of the fourth terminal 14 and the sixth terminal 16 are arranged in a staggered manner with different lengths protruding outward. In the example of FIG. 6, the fourth terminal 14 and the sixth terminal 16 protrude longer than the fifth terminal 15 and the seventh terminal 17, but the fifth terminal 15 and the seventh terminal 17 may protrude longer than the fourth terminal 14 and the sixth terminal 16.

By orienting the leading ends of the first terminal 8, the second terminal 10, the third terminal 12, the fourth terminal 14, the fifth terminal 15, the sixth terminal 16, and the seventh terminal 17 in the perpendicular direction, the fourth terminal 14, the fifth terminal 15, the sixth terminal 16, and the seventh terminal 17 can be connected to a gate driver disposed in a direction perpendicular to the power module without mounting the gate driver on a printed circuit board.

According to the fifth preferred embodiment, the connection of the gate driver is simplified, and the mounting area of the components arranged on the printed circuit board can be reduced. In addition, it is possible to reduce the wiring inductance and to make it less affected by electromagnetic compatibility (EMC).

### First Modification of Fifth Preferred Embodiment

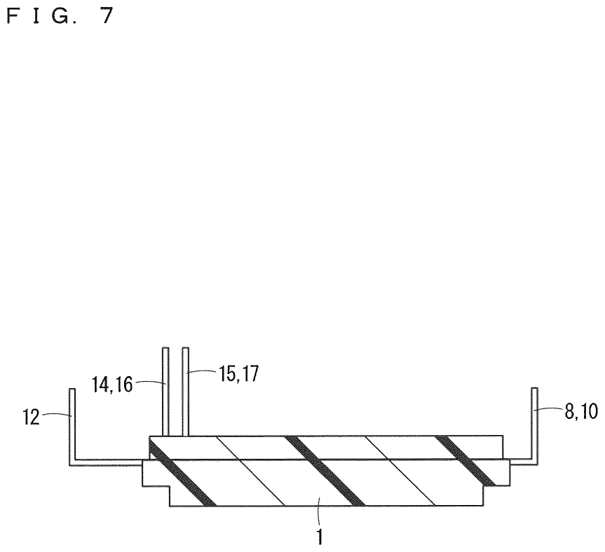

FIG. 7 is a side view illustrating a configuration of a power module according to a first modification of the fifth preferred embodiment. In the power module according to the first modification of the fifth preferred embodiment, at least one of the first terminal 8, the second terminal 10, the third terminal 12, the fourth terminal 14, the fifth terminal 15, the sixth terminal 16, and the seventh terminal 17 protrudes in the perpendicular direction from the upper surface of a package 1. The other configurations are similar to those of the power module (FIG. 6) according to the fifth preferred embodiment, and thus the detailed description thereof is omitted here.

In the example of FIG. 7, the fourth terminal 14, the fifth terminal 15, the sixth terminal 16, and the seventh terminal 17 protrude in the perpendicular direction from the upper surface of the package 1. As a result, the lengths of the fourth terminal 14, the fifth terminal 15, the sixth terminal 16, and the seventh terminal 17 can be shortened.

Although only the fourth terminal 14, the fifth terminal 15, the sixth terminal 16, and the seventh terminal 17 protrude in the perpendicular direction from the upper surface of the package 1 in the example of FIG. 7, only the first terminal 8, the second terminal 10, and the third terminal 12 may protrude in the perpendicular direction from the upper surface of the package 1, and which terminal is protruded in the perpendicular direction from the upper surface of the package 1 is freely selected.

According to the first modification of the fifth preferred embodiment, the connection of a gate driver is simplified, and the mounting area of components arranged on a printed circuit board can be reduced. In addition, it is possible to reduce the wiring inductance and to make it less affected by electromagnetic compatibility (EMC).

### Second Modification of Fifth Preferred Embodiment

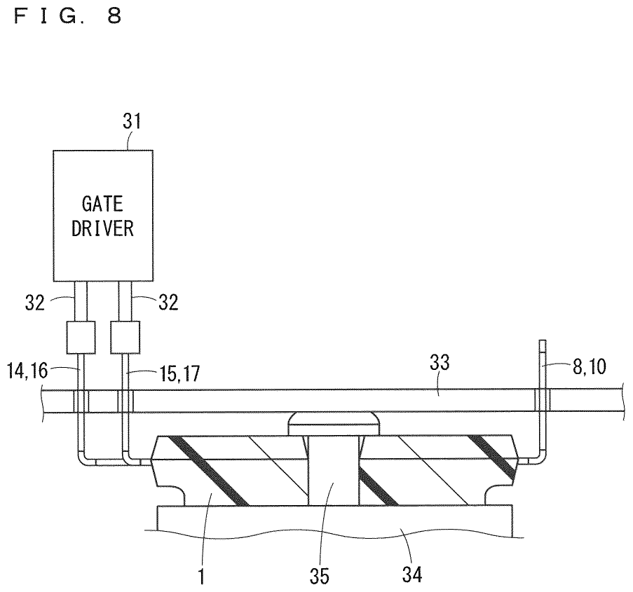

FIG. 8 is a side view illustrating a configuration of a power module according to a second modification of the fifth preferred embodiment. In the power module according to the second modification of the fifth preferred embodiment, the leading end portion of each of the fourth terminal 14, the fifth terminal 15, the sixth terminal 16, and the seventh terminal 17 has a female shape. The other configurations are similar to those of the power module (FIG. 6) according to the fifth preferred embodiment, and thus the detailed description thereof is omitted here.

As illustrated in FIG. 8, a package 1 of the power module is attached to a cooling fin 34 by a screw 35. The leading end portion of each of the fourth terminal 14, the fifth terminal 15, the sixth terminal 16, and the seventh terminal 17 are directly connected to a gate driver terminal 32 of a gate driver 31 via a printed circuit board 33. Instead of the gate driver 31, a hybrid integrated circuit (IC) may be used.

According to the second modification of the fifth preferred embodiment, it is possible to improve the mountability of the gate driver 31 or the hybrid IC.

Note that each of the fourth terminal 14, the fifth terminal 15, the sixth terminal 16, and the seventh terminal 17 may protrude in the perpendicular direction from the upper surface of the package 1 as in the first modification of the fifth preferred embodiment (see FIG. 7).

It is to be noted that, within the scope of the present disclosure, the above preferred embodiments may be freely combined with each other, or each of the above preferred embodiments may be modified or omitted as appropriate.

### Appendix

Various aspects of the present disclosure will be collectively described below as appendix.

### (Appendix 1)

A power module comprising a package and at least one switching device group disposed inside the package, wherein
the switching device group includes:
   a first switching device that is disposed inside the package and serves as an upper arm;
   a second switching device that is disposed inside the package and serves as a lower arm;
   a first frame that is disposed inside the package, is connected to a high voltage potential part of the first switching device, and has a first terminal that is a portion protruding outside the package;
   a second frame that is disposed inside the package, is connected to a reference potential part of the second switching device, and has a second terminal that is a portion protruding outside the package;
   a third frame that is disposed inside the package, is connected to each of a reference potential part of the first switching device and a high voltage potential part of the second switching device, and has a third terminal that is a portion protruding outside the package;
   a fourth terminal that is connected to a control potential part of the first switching device without passing through the first frame, the second frame, and the third frame and protrudes outside the package;
   a fifth terminal that is connected to the reference potential part of the first switching device without passing through the first frame, the second frame, and the third frame and protrudes outside the package;
   a sixth terminal that is connected to a control potential part of the second switching device without passing through the first frame, the second frame, and the third frame and protrudes outside the package; and
   a seventh terminal that is connected to the reference potential part of the second switching device without passing through the first frame, the second frame, and the third frame and protrudes outside the package.

### (Appendix 2)

The power module according to Appendix 1, wherein package inductance that is inductance between the first terminal and the second terminal is 20 nH or less.

### (Appendix 3)

The power module according to Appendix 1 or 2, wherein
the at least one switching device group includes a plurality of switching device groups, and
each of the switching device groups is aligned in one direction inside the package.

### (Appendix 4)

The power module according to Appendix 3, wherein two or more of the switching device groups are disposed inside the package to form a full-bridge circuit.

### (Appendix 5)

The power module according to Appendix 3, wherein three or more of the switching device groups are disposed inside the package to form a three-phase structure.

### (Appendix 6)

The power module according to any one of Appendixes 1 to 5, wherein
a first connection point at which one end of a wire connecting the reference potential part of the first switching device and the third frame is connected to the reference potential part of the first switching device is located at a center of the first switching device, and
a second connection point at which one end of a wire connecting the reference potential part of the first switching device and the fifth terminal is connected to the reference potential part of the first switching device is located at an end of the first switching device.

### (Appendix 7)

The power module according to any one of Appendixes 1 to 5, wherein
a first connection point at which one end of a wire connecting the reference potential part of the first switching device and the third frame is connected to the reference potential part of the first switching device is located closer to an end with respect to a center of the first switching device, and
a second connection point at which one end of a wire connecting the reference potential part of the first switching device and the fifth terminal is connected to the reference potential part of the first switching device is located on a side opposite to the first connection point with respect to the center of the first switching device.

### (Appendix 8)

The power module according to Appendix 6 or 7, wherein the second connection point is adjacent to a third connection point at which one end of a wire connecting the control potential part of the first switching device and the fourth terminal is connected to the control potential part of the first switching device.

### (Appendix 9)

The power module according to Appendix 6 or 7, wherein the second connection point has a longer distance from the first connection point than a third connection point at which one end of a wire connecting the control potential part of the first switching device and the fourth terminal is connected to the control potential part of the first switching device.

### (Appendix 10)

The power module according to any one of Appendixes 1 to 9, wherein
a fourth connection point at which one end of a wire connecting the reference potential part of the second switching device and the second frame is connected to the reference potential part of the second switching device is located at a center of the second switching device, and
a fifth connection point at which one end of a wire connecting the reference potential part of the second switching device and the seventh terminal is connected to the reference potential part of the second switching device is located at an end of the second switching device.

### (Appendix 11)

The power module according to any one of Appendixes 1 to 9, wherein
a fourth connection point at which one end of a wire connecting the reference potential part of the second switching device and the second frame is connected to the reference potential part of the second switching device is located closer to an end with respect to a center of the second switching device, and
a fifth connection point at which one end of a wire connecting the reference potential part of the second switching device and the seventh terminal is connected to the reference potential part of the second switching device is located on a side opposite to the fourth connection point with respect to the center of the second switching device.

### (Appendix 12)

The power module according to Appendix 10 or 11, wherein the fifth connection point is adjacent to a sixth connection point at which one end of a wire connecting the control potential part of the second switching device and the sixth terminal is connected to the control potential part of the second switching device.

### (Appendix 13)

The power module according to Appendix 10 or 11, wherein the fifth connection point has a longer distance from the fourth connection point than a sixth connection point at which one end of a wire connecting the control potential part of the second switching device and the sixth terminal is connected to the control potential part of the second switching device.

### (Appendix 14)

The power module according to any one of Appendixes 1 to 13, wherein
the first terminal and the second terminal are disposed on a first side of the package, and
the third terminal, the fourth terminal, the fifth terminal, the sixth terminal, and the seventh terminal are disposed on a second side different from the first side of the package.

### (Appendix 15)

The power module according to any one of Appendixes 1 to 14, wherein a leading end of each of the first terminal, the second terminal, the third terminal, the fourth terminal, the fifth terminal, the sixth terminal, and the seventh terminal is oriented in a direction perpendicular to the first frame, the second frame, and the third frame.

### (Appendix 16)

The power module according to Appendix 15, wherein at least one of the first terminal, the second terminal, the third terminal, the fourth terminal, the fifth terminal, the sixth terminal, and the seventh terminal protrudes in a perpendicular direction from an upper surface of the package.

### (Appendix 17)

The power module according to Appendix 15 or 16, wherein each of the fourth terminal, the fifth terminal, the sixth terminal, and the seventh terminal has a leading end having a female shape.

While the disclosure has been shown and described in detail, the foregoing description is in all aspects illustrative and not restrictive. It is therefore understood that numerous modifications and variations can be devised.

What is claimed is:

1. A power module comprising a package and at least one switching device group disposed inside the package, wherein
the switching device group includes:
a first switching device that is disposed inside the package and serves as an upper arm;
a second switching device that is disposed inside the package and serves as a lower arm;
a first frame that is disposed inside the package, is connected to a high voltage potential part of the first switching device, and has a first terminal that is a portion protruding outside the package;
a second frame that is disposed inside the package, is connected to a reference potential part of the second switching device, and has a second terminal that is a portion protruding outside the package;
a third frame that is disposed inside the package, is connected to each of a reference potential part of the first switching device and a high voltage potential part of the second switching device, and has a third terminal that is a portion protruding outside the package;
a fourth terminal that is connected to a control potential part of the first switching device without passing through the first frame, the second frame, and the third frame and protrudes outside the package;
a fifth terminal that is connected to the reference potential part of the first switching device without passing through the first frame, the second frame, and the third frame and protrudes outside the package;
a sixth terminal that is connected to a control potential part of the second switching device without passing through the first frame, the second frame, and the third frame and protrudes outside the package; and
a seventh terminal that is connected to the reference potential part of the second switching device without passing through the first frame, the second frame, and the third frame and protrudes outside the package.

2. The power module according to claim 1, wherein package inductance that is inductance between the first terminal and the second terminal is 20 nH or less.

3. The power module according to claim 1, wherein
the at least one switching device group includes a plurality of switching device groups, and
each of the switching device groups is aligned in one direction inside the package.

4. The power module according to claim 3, wherein two or more of the switching device groups are disposed inside the package to form a full-bridge circuit.

5. The power module according to claim 3, wherein three or more of the switching device groups are disposed inside the package to form a three-phase structure.

6. The power module according to claim 1, wherein
a first connection point at which one end of a wire connecting the reference potential part of the first switching device and the third frame is connected to the reference potential part of the first switching device is located at a center of the first switching device, and
a second connection point at which one end of a wire connecting the reference potential part of the first switching device and the fifth terminal is connected to the reference potential part of the first switching device is located at an end of the first switching device.

7. The power module according to claim 1, wherein
first connection point at which one end of a wire connecting the reference potential part of the first switching device and the third frame is connected to the reference potential part of the first switching device is located closer to an end with respect to a center of the first switching device, and
a second connection point at which one end of a wire connecting the reference potential part of the first switching device and the fifth terminal is connected to the reference potential part of the first switching device is located on a side opposite to the first connection point with respect to the center of the first switching device.

8. The power module according to claim 6, wherein the second connection point is adjacent to a third connection point at which one end of a wire connecting the control potential part of the first switching device and the fourth terminal is connected to the control potential part of the first switching device.

9. The power module according to claim 6, wherein the second connection point has a longer distance from the first connection point than a third connection point at which one end of a wire connecting the control potential part of the first switching device and the fourth terminal is connected to the control potential part of the first switching device.

10. The power module according to claim 1, wherein
a fourth connection point at which one end of a wire connecting the reference potential part of the second switching device and the second frame is connected to the reference potential part of the second switching device is located at a center of the second switching device, and
a fifth connection point at which one end of a wire connecting the reference potential part of the second switching device and the seventh terminal is connected to the reference potential part of the second switching device is located at an end of the second switching device.

11. The power module according to claim 1, wherein
a fourth connection point at which one end of a wire connecting the reference potential part of the second switching device and the second frame is connected to the reference potential part of the second switching device is located closer to an end with respect to a center of the second switching device, and
a fifth connection point at which one end of a wire connecting the reference potential part of the second switching device and the seventh terminal is connected to the reference potential part of the second switching device is located on a side opposite to the fourth connection point with respect to the center of the second switching device.

12. The power module according to claim 10, wherein the fifth connection point is adjacent to a sixth connection point at which one end of a wire connecting the control potential part of the second switching device and the sixth terminal is connected to the control potential part of the second switching device.

13. The power module according to claim 10, wherein the fifth connection point has a longer distance from the fourth connection point than a sixth connection point at which one end of a wire connecting the control potential part of the second switching device and the sixth terminal is connected to the control potential part of the second switching device.

14. The power module according to claim 1, wherein
the first terminal and the second terminal are disposed on a first side of the package, and
the third terminal, the fourth terminal, the fifth terminal, the sixth terminal, and the seventh terminal are disposed on a second side different from the first side of the package.

15. The power module according to claim 1, wherein a leading end of each of the first terminal, the second terminal, the third terminal, the fourth terminal, the fifth terminal, the sixth terminal, and the seventh terminal is oriented in a direction perpendicular to the first frame, the second frame, and the third frame.

16. The power module according to claim 15, wherein at least one of the first terminal, the second terminal, the third terminal, the fourth terminal, the fifth terminal, the sixth terminal, and the seventh terminal protrudes in a perpendicular direction from an upper surface of the package.

17. The power module according to claim 15, wherein each of the fourth terminal, the fifth terminal, the sixth terminal, and the seventh terminal has a leading end having a female shape.
